(19) United States
(12) Patent Application Publication
(10) Pub. No.: US 2026/0049951 A1
(43) Pub. Date: Feb. 19, 2026

(54) PATTERN INSPECTION APPARATUS

(71) Applicant: NuFlare Technology, Inc., Yokohama-shi (JP)

(72) Inventors: Hiroyuki NAGAHAMA, Niiza-shi (JP); Ryoichi HIRANO, Setagaya-ku (JP)

(73) Assignee: NuFlare Technology, Inc., Yokohama-shi (JP)

(21) Appl. No.: 19/265,022

(22) Filed: Jul. 10, 2025

(30) Foreign Application Priority Data
Aug. 13, 2024 (JP) 2024-135117

(51) Int. Cl. G01N 21/956; G01N 21/88; G02B 7/08; G02B 7/28; G02B 27/30; G03F 7/00

(52) U.S. Cl. CPC G01N 21/956; G01N 21/8851; G03F 7/7065; G03F 7/70666; G03F 7/706837; G03F 7/706845; G03F 7/706849; G03F 7/706851; G01N 2021/8887; G01N 2021/95676; G01N 2201/0633; G02B 7/08; G02B 7/28; G02B 27/30

(57) ABSTRACT

According to one aspect of the present invention, a pattern inspection apparatus includes: an imaging sensor including a plurality of first detection elements that detect light flux transmitted through or reflected by a target object illuminated with inspection Light and capture a pattern image of the target object, and a plurality of second detection elements that are arranged adjacent to the plurality of first detection elements, detect Light fluxes obtained by shifting a focus position of the light flux front side and rear side, and capture images for focus adjustment; an adjustment mechanism configured to adjust a focal position of the light flux by using the images for the focus adjustment captured by the plurality of second detection elements; and a comparison circuit configured to compare the pattern image captured by the plurality of first detection elements and a predetermined reference image.

### CROSS-REFERENCE TO RELATED APPLICATION

This application is based upon and claims the benefit of priority from prior Japanese Patent Application No. 2024-135117 filed on Aug. 13, 2024 in Japan, the entire contents of which are incorporated herein by reference.

### BACKGROUND OF THE INVENTION

### Field of the Invention

Embodiments described herein relate generally to a pattern inspection apparatus. For example, the present invention relates to an apparatus for inspecting pattern defects of an exposure mask used for semiconductor manufacturing and a focal position adjustment method of the apparatus.

### Related Art

In recent years, circuit linewidths required for semiconductor elements are getting narrower in accordance with higher integration and larger capacity of large scale integrated circuits (LSI). These semiconductor elements are manufactured by forming a circuit by exposing and transferring a pattern onto a wafer by a reduction projection exposure device referred to as a so-called stepper using an original image pattern (also referred to as a mask or a reticle. Hereinafter, collectively referred to as a mask.) on which a circuit pattern is formed.

In addition, improvement of yield is essential for the manufacture of LSI requiring a large manufacturing cost. One of the major factors for lowering the yield is a pattern defect of a mask used when an ultrafine pattern is exposed and transferred on a semiconductor wafer by a photolithography technique. In recent years, along with miniaturization of LSI pattern dimensions formed on a semiconductor wafer, dimensions to be detected as pattern defects are extremely small. Therefore, there is a need to increase the accuracy of a pattern inspection apparatus that inspects defects of a transfer mask used for LSI manufacturing.

Examples of the inspection method include “die to die inspection” for comparing optical image data obtained by imaging the same pattern at different locations on the same mask and “die to database inspection” for inputting writing data (design data) converted into a device input format for a writing apparatus to input when a pattern is written using pattern-designed CAD data as a mask to an inspection apparatus, generating a reference image based on the writing data, and comparing the reference image with an optical image to be measurement data obtained by imaging the pattern.

In such an inspection apparatus, there is a need to clearly collect a pattern image on a mask of an inspection object. However, since there is a finite focal depth in the optical system of the inspection apparatus, there is a need to keep the inspection plane of the inspection object within the focal depth of the optical system during the inspection. In other words, it is required to maintain the contrast of the captured image within an allowable range.

Therefore, in the inspection apparatus, in addition to the inspection optical system for image capturing, an autofocus mechanism that detects the displacement of the inspection object in the height direction with respect to the inspection optical system and adjusts the height position is adopted.

With the recent miniaturization of patterns, shortening of the wavelength of inspection light is progressing. Accordingly, the focal depth of the inspection optical system becomes shallower. Therefore, although the accuracy of the measurement system of the independent autofocus mechanism installed near the inspection optical system is sufficient in the related art, unless the (In-situ) measurement using the inspection optical system itself is performed, various fluctuation factors (dependency of temperature/mechanical deformation) of the inspection optical system cannot be detected, and the focus cannot be highly accurately adjusted. Therefore, a mode in which an inspection optical system is partially used is adopted as the autofocus mechanism (see Published Unexamined Japanese Patent Application No. 2020-125941 (JP-A-2020-125941), for example).

In such an autofocus mechanism, an autofocus image is projected near the inspection visual field of the transmission inspection or/and the reflection inspection in the scanning direction, an autofocus signal indicating defocus of the autofocus image is fed back, and the stage height is adjusted so that focusing is performed. However, such a method has a problem that accuracy may be insufficient depending on illumination conditions and patterns formed on a target object.

### BRIEF SUMMARY OF THE INVENTION

According to one aspect of the present invention, a pattern inspection apparatus includes:
a movable stage on which a target object on which a pattern is formed is placed;
an imaging sensor including a plurality of first detection elements that detect light flux transmitted through or reflected by the target object illuminated with inspection light and capture a pattern image of the target object, and a plurality of second detection elements that are arranged adjacent to the plurality of first detection elements, detect light fluxes obtained by shifting a focus position of the light flux front side and rear side, and capture images for focus adjustment;
an adjustment mechanism configured to adjust a focal position of the light flux by using the images for the focus adjustment captured by the plurality of second detection elements; and
a comparison circuit configured to compare the pattern image captured by the plurality of first detection elements and a predetermined reference image.

### BRIEF DESCRIPTION OF THE DRAWINGS

FIG. 1 is a configuration diagram illustrating a configuration of a pattern inspection apparatus according to First Embodiment;

FIG. 2 is a conceptual diagram illustrating an inspection region according to First Embodiment;

FIG. 3 is a diagram illustrating an example of each region on a substrate surface according to First Embodiment;

FIG. 4 is a diagram illustrating an example of an array of detection elements of an imaging sensor according to First Embodiment;

FIG. 5 is a cross-sectional view illustrating an example of a configuration of an optical mechanism for focus detection and an example of an imaging sensor according to First Embodiment;

FIG. 6 is a diagram illustrating an example of a focus detection method according to First Embodiment;

FIG. 7 is a diagram illustrating an example of a configuration in a case where a plurality of regions are simultaneously inspected according to First Embodiment;

FIG. 8 is a diagram illustrating an example of an internal configuration of a comparison circuit according to First Embodiment;

FIG. 9 is a diagram illustrating an example of an internal configuration of an autofocus control circuit according to First Embodiment;

FIG. 10 is a diagram illustrating filter processing according to First Embodiment;

FIG. 11 is a configuration diagram illustrating a configuration of a pattern inspection apparatus according to Second Embodiment;

FIG. 12 is a diagram illustrating an example of a field stop image of inspection light and measurement light according to Second Embodiment;

FIG. 13 is a diagram illustrating arrangement positions of a front focal illumination pattern and a rear focal illumination pattern according to Second Embodiment; and

FIG. 14 is a diagram illustrating an example of a front view of the front focal illumination pattern and the rear focal illumination pattern according to Second Embodiment.

### DETAILED DESCRIPTION OF THE INVENTION

Hereinafter, embodiments provide an inspection apparatus capable of focus adjustment without depending on illumination conditions or patterns formed on a target object.

### First Embodiment

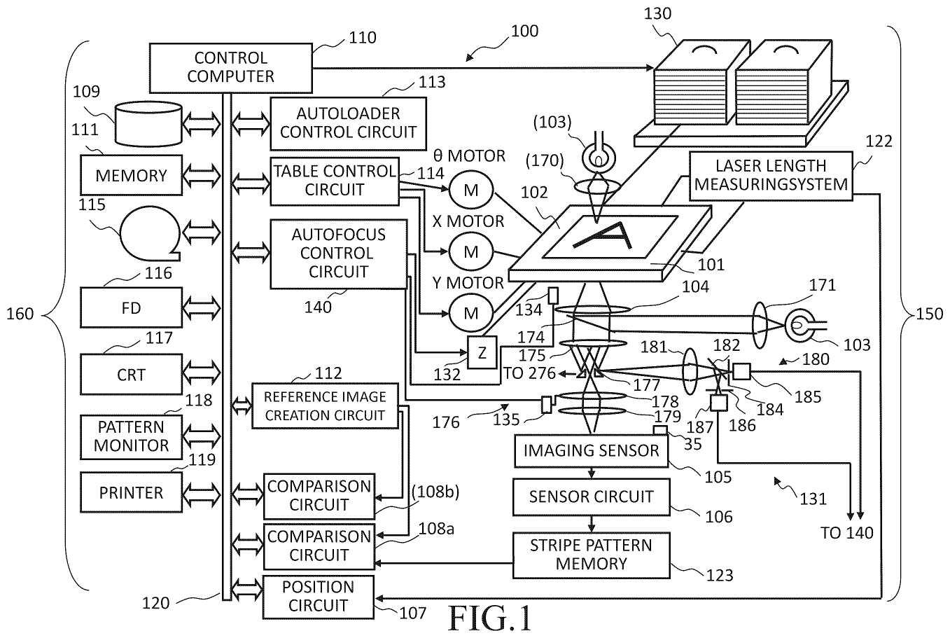

FIG. 1 is a configuration diagram illustrating a configuration of a pattern inspection apparatus according to First Embodiment. In FIG. 1, an inspection apparatus 100 that inspects a defect of a pattern formed on a substrate to be inspected, for example, a mask, includes an optical image acquisition mechanism 150 and a control system circuit 160.

The optical image acquisition mechanism 150 includes a light source 103, a reflection illumination optical system 171, a movably arranged XYθ table 102, an objective lens 104, a beam splitter 174, a first image forming lens 175, a separation mirror 177, a detection optical system 176, an autofocus mechanism 131, an imaging sensor 105, a sensor circuit 106, a stripe pattern memory 123, a laser length measuring system 122, and an autoloader 130. When transmission inspection using transmitted light is performed, a transmitted illumination optical system 170 is further arranged.

The detection optical system 176 includes, for example, a collimator lens 178 and an image forming lens 179.

When only the reflection inspection using reflected light is performed without performing the transmission inspection, the transmitted illumination optical system 170 may be omitted. When both the transmission inspection and the reflection inspection are simultaneously performed, a detection optical system, an imaging sensor, a sensor circuit, and a stripe pattern memory described below may be further added, so that an image for the reflection inspection may be captured by the imaging sensor 105, and an image for the transmission inspection may be captured by the added imaging sensor.

The autofocus mechanism 131 includes a focus optical system 180, a light amount sensor 185 (first light amount sensor), a light amount sensor 187 (second light amount sensor), a Z drive mechanism 132, and a position sensor 134. The focus optical system 180, the light amount sensor 185, and the light amount sensor 187 configure a part of the confocal sensor.

The focus optical system 180 includes an image forming optical system 181, a beam splitter 182, a slit plate 184, and a slit plate 186. When a substrate 101 is irradiated with measurement light using a portion of light generated from a light source, the focus optical system 180 guides light flux transmitted through or reflected by the substrate 101 to the light amount sensor 185 and the light amount sensor 187. The beam splitter 182 is disposed in front of a design focal position. The slit plate 184 is disposed at a front focal position (front pin position) and receives light transmitted through the beam splitter 182. The light amount sensor 185 measures the amount of light passing through the slit plate 184 disposed at the front focal position (front pin position). The slit plate 186 is disposed at a rear focal position (rear pin position) and receives light split by the beam splitter 182. The light amount sensor 187 measures the amount of light passing through the slit plate 186 disposed at the rear focal position (rear pin position).

The substrate 101 conveyed from the autoloader 130 is disposed on the XYθ table 102 (an example of a stage). Examples of the substrate 101 include a photomask for exposure for transferring a pattern to a semiconductor substrate such as a wafer. A plurality of figure patterns to be inspected are formed in the photomask. The substrate 101 is disposed on the XYθ table 102, for example, with the pattern formation surface facing downward. This is an example of a stage of the XYθ table 102.

A line sensor or a two-dimensional sensor is used as the imaging sensor 105. For example, a time delay integration (TDI) sensor is preferably used.

Furthermore, an optical mechanism 35 is disposed in front of the end portions of the plurality of detection elements of the imaging sensor 105 in the optical axis direction.

In the control system circuit 160, a control computer 110 that controls the entire inspection apparatus 100 is connected, via a bus 120, to a position circuit 107, a comparison circuit 108, a reference image creation circuit 112, an autoloader control circuit 113, a table control circuit 114, an autofocus control circuit 140, a magnetic disk device 109, a memory 111, a magnetic tape device 115, a flexible disk device (FD) 116, a CRT 117, a pattern monitor 118, and a printer 119. In addition, the imaging sensor 105 is connected to the stripe pattern memory 123, and the stripe pattern memory 123 is connected to the comparison circuit 108. The reference image creation circuit 112 is connected to the comparison circuit 108. Note that the plurality of comparison circuits 108 such as a comparison circuit 108a, a comparison circuit 108b, . . . , and the like are preferably arranged.

The position sensor 134 measures a height position of a reference surface (for example, a glass substrate surface) of the pattern formed surface of the substrate 101. The height position of the back surface of the XYθ table 102 to be measured is preferably adjusted to be, for example, the same height as the reference surface of the pattern formed surface of the substrate 101 when the substrate 101 is placed on the XYθ table 102. As a result, the position sensor 134 may measure the height position of the reference surface of the pattern formed surface of the substrate 101 by measuring the height position of the back surface of the XYθ table 102.

The output of the position sensor 134 is connected to the autofocus control circuit 140. In addition, the output of the light amount sensors 185 and 187 is connected to the autofocus control circuit 140.

Note that a series of “circuits” such as the position circuit 107, the comparison circuit 108, the reference image creation circuit 112, the autoloader control circuit 113, the table control circuit 114, and the autofocus control circuit 140 includes a processing circuit. Such a processing circuit includes an electric circuit, a computer, a processor, a circuit board, a quantum circuit, a semiconductor device, or the like. Each circuit may be configured using the same processing circuit (one processing circuit), or different processing circuits (separate processing circuits) may be used. For example, a series of “circuits” such as the position circuit 107, the comparison circuit 108, the reference image creation circuit 112, the autoloader control circuit 113, the table control circuit 114, and the autofocus control circuit 140 may be configured and executed by the control computer 110. Input data necessary for the position circuit 107, the comparison circuit 108, the reference image creation circuit 112, the autoloader control circuit 113, the table control circuit 114, and the autofocus control circuit 140, or a result of calculation is stored in a memory (not illustrated) or the memory 111 in each circuit each time. Input data necessary for the control computer 110 or a calculation result is stored in a memory (not illustrated) or a memory 111 in the control computer 110 each time. The program for executing the processor or the like may be recorded in a recording medium such as the magnetic disk device 109, the magnetic tape device 115, the FD 116, or a read only memory (ROM).

In the inspection apparatus 100, a reflection inspection optical system and/or a transmission inspection optical system is mounted as the inspection optical system. A high magnification reflection inspection optical system is configured with the light source 103, the reflection illumination optical system 171, the beam splitter 174, the objective lens 104, the XYθ table 102, and the detection optical system 176. Alternatively, a high magnification transmission inspection optical system is configured with the light source 103, the transmitted illumination optical system 170, the XYθ table 102, the objective lens 104, and a detection optical system (not illustrated).

Also, the XYθ table 102 is driven by the table control circuit 114 under the control of the control computer 110. The XYθ table is movable by a drive system such as a three-axis (X-Y-θ) motor that drives in the X direction, the Y direction, and the θ direction. As the X motor, the Y motor, and the θ motor, for example, step motors can be used. The XYθ table 102 is movable in the horizontal direction and the rotational direction by motors of XYθ axes. The XYθ table 102 is an example of a stage. Then, the moving position of the substrate 101 disposed on the XYθ table 102 is measured by the laser length measuring system 122 and supplied to the position circuit 107. Also, the conveyance of the substrate 101 from the autoloader 130 to the XYθ table 102 and the conveyance processing of the substrate 101 from the XYθ table 102 to the autoloader 130 are controlled by the autoloader control circuit 113.

Also, the XYθ table 102 is driven in the z direction by the Z drive mechanism 132 controlled by the autofocus control circuit 140. As the Z drive mechanism 132, for example, a piezoelectric element or a step motor is preferably used. The height position of the pattern formed surface (glass substrate surface) of the substrate 101 measured by the position sensor 134 is output to the autofocus control circuit 140.

Furthermore, a drive mechanism 135 controlled by the autofocus control circuit 140 moves at least one of the collimator lens 178 and the image forming lens 179 in the optical axis direction.

Pattern writing data (design data) to be a basis of pattern formation of the substrate 101 to be inspected is input from the outside of the inspection apparatus 100 and stored in the magnetic disk device 109. A plurality of types of figure patterns are defined in the pattern writing data, and each figure pattern is usually configured by a combination of a plurality of element figures. Note that the pattern writing data may include a figure pattern including one figure. On the inspected substrate 101, corresponding patterns are formed based on the respective figure patterns defined in the pattern writing data.

Here, in FIG. 1, components necessary for describing First Embodiment are described. It is obvious that the inspection apparatus 100 may normally include other necessary configurations.

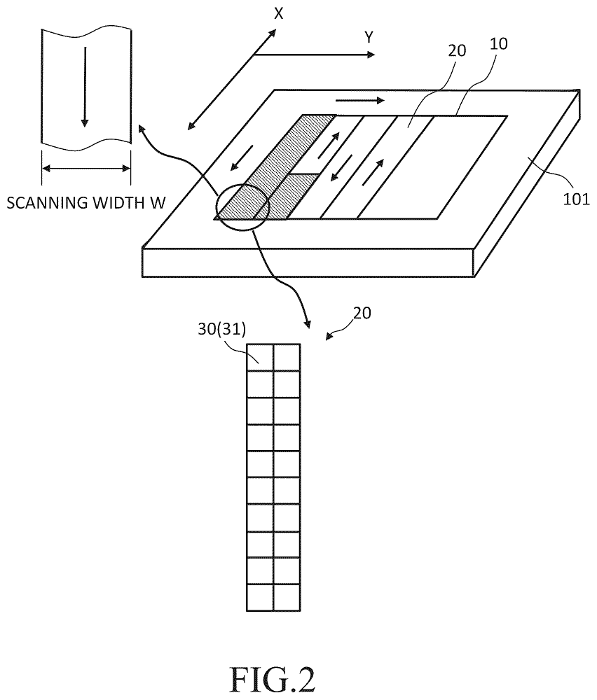

FIG. 2 is a conceptual diagram illustrating an inspection region according to First Embodiment. As illustrated in FIG. 2, the inspection region 10 (the entire inspection region) of the substrate 101 is virtually divided into a plurality of strip-shaped inspection stripes 20 (stripe regions) having a width W, for example, in the Y direction. The width W is preferably set to a scan width of a detection element group that captures an inspection image among the plurality of detection elements of the imaging sensor 105. Then, the inspection apparatus 100 acquires an image (stripe region image) for each inspection stripe 20. For each of the inspection stripes 20, an image of a figure pattern arranged in the inspection stripe 20 is captured toward the longitudinal direction (X direction) of the inspection stripe 20 using a laser beam (inspection light). In order to prevent missing of an image, the plurality of inspection stripes 20 is preferably set so that the adjacent inspection stripes 20 overlap each other with a predetermined margin width.

The optical image is acquired while the imaging sensor 105 relatively continuously moves in the X direction by the movement of the XYθ table 102. The imaging sensor 105 continuously captures optical images having the width Was illustrated in FIG. 2. In First Embodiment, after an optical image in one inspection stripe 20 is captured, the imaging sensor 105 continuously captures optical images having the width W while moving to the position of the next inspection stripe 20 in the Y direction and then moving in the opposite direction. That is, the images are repeatedly captured in a forward (FWD)-backward (BWD) direction that are opposite directions in the forward path and the backward path.

In actual inspection, the stripe region image of each inspection stripe 20 is divided into images of a plurality of rectangular frame regions 30 as illustrated in FIG. 2. Then, the inspection is performed for each image in the frame region 30. For example, the image is divided into a size of 512×512 pixels. Therefore, a reference image to be compared with a frame image 31 of the frame region 30 is similarly created for each frame region 30.

Here, the imaging direction is not limited to repetition of forward (FWD)-backward (BWD). The images may be captured in one direction. For example, the imaging direction may be repetition of FWD-FWD. Alternatively, the imaging direction may be repetition of BWD-BWD.

As described above, the inspection apparatus 100 includes the autofocus mechanism 131 that detects the displacement in the height direction of the substrate 101 that is the inspection object with respect to the inspection optical system in addition to the inspection optical system (the reflection inspection optical system and/or the transmission inspection optical system).

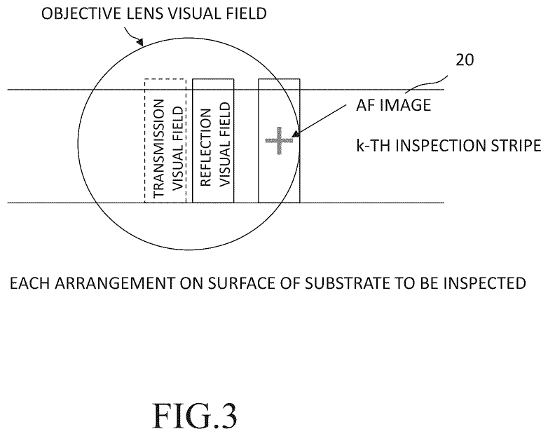

FIG. 3 is a diagram illustrating an example of each region on the substrate surface according to First Embodiment. In FIG. 3, when the scanning operation of each inspection stripe is performed, a substrate is irradiated with each piece of inspection light so that a reflection visual field (field stop image) of the inspection light for reflection inspection and an AF image for autofocus (AF) are arranged in a scanning direction with respect to a target inspection stripe 20. In the case that the transmission inspection is performed, the substrate is irradiated with each piece of inspection light so that the transmission visual field (field stop image) of the inspection light for the transmission inspection is aligned with the reflection visual field in the scanning direction. At this time, it is preferable to dispose the AF image for autofocus (AF) near the front in the scanning direction with respect to each inspection visual field.

Note that the width of each inspection stripe 20 is formed to be slightly smaller than the size of each inspection visual field in the longitudinal direction. The image of the light flux portion transmitted or reflected by the substrate 101 by irradiating an inspection visual field portion protruding from the inspection stripe 20 is captured as the image for focus detection in First Embodiment.

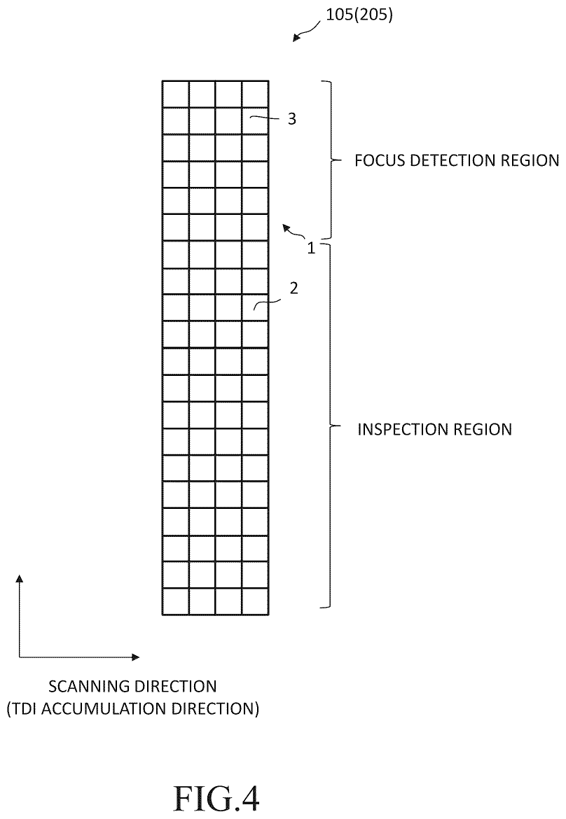

FIG. 4 is a diagram illustrating an example of an array of detection elements of the imaging sensor according to First Embodiment. In the example of FIG. 4, a case where a TDI sensor is used as the imaging sensor 105 (205) is illustrated. The TDI sensor includes a plurality of detection elements 1 (photosensor elements) arrayed two-dimensionally. When each detection element 1 captures an image, a predetermined image accumulation time is set. In the TDI sensor, the outputs of the plurality of detection elements 1 aligned in the scanning direction are integrated and output. The plurality of detection elements 1 aligned in the scan direction capture images of the same pixel while shifting the time according to the movement of the XYθ table 102. When a line sensor is used as the imaging sensor 105, a plurality of detection elements are arranged to be aligned in a direction orthogonal to the scanning direction.

Note that the imaging sensor 205 is used in a case where transmission inspection is performed.

The plurality of detection elements 1 of the imaging sensor 105 includes a plurality of detection elements 2 (first detection elements) that capture a pattern image to be an inspection image of the substrate 101 and a plurality of detection elements 3 (second detection elements) that are arranged adjacent to the plurality of detection elements 2 and capture an image for focus detection. The plurality of detection elements 2 arranged in the inspection region detect a light flux transmitted through or reflected by the substrate 101 (target object) illuminated by the inspection light and capture pattern images of the substrate 101. The plurality of detection elements 3 arranged in the focus detection region detect light fluxes obtained by shifting a focus position of the light flux front side and rear side (forward and backward) and capture an image for focus detection.

When a TDI sensor is used as the imaging sensor 105 (205), the imaging sensor 105 (205) uses a time delay integration (TDI) method and has the plurality of detection elements 3 at end portions in a direction orthogonal to a TDI accumulation direction. The number of the plurality of detection elements 3 is smaller than the number of the plurality of detection elements 2. The example of FIG. 4 illustrates a case where about two to 10, for example, six detection elements from the end portion are used as the detection elements 3 in the direction orthogonal to the TDI accumulation direction. The number of detection elements in the TDI accumulation direction is similar to that of the detection element 2.

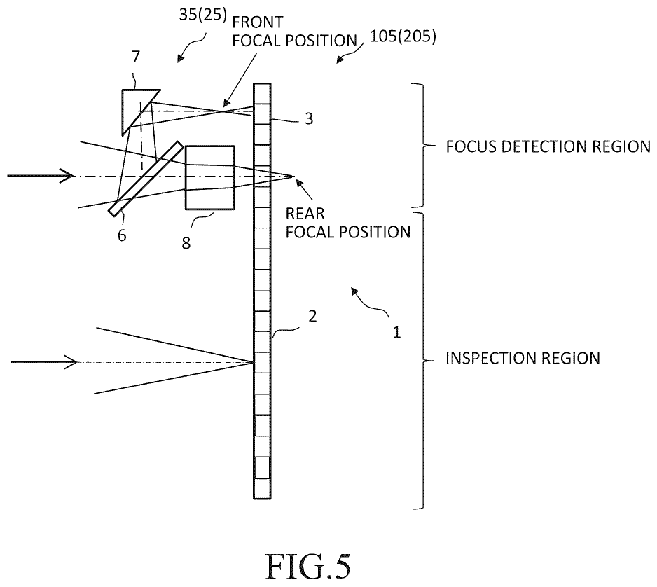

FIG. 5 is a cross-sectional view illustrating an example of a configuration of the optical mechanism for focus detection and an example of the imaging sensor according to First Embodiment. In FIG. 5, the optical mechanism 35 (25) is disposed in front of the plurality of detection elements 3 of the imaging sensor 105 (205) in the optical axis direction. The optical mechanism 35 (25) includes a half mirror 6, a mirror 7, and a glass block 8. The optical mechanism 35 (25) moves the focal position of the light flux with which the region for focus detection of the imaging sensor 105 (205) is irradiated to the front side and the back side. Specifically, it acts as follows. A Light flux with which a focus detection region of the imaging sensor 105 (205) is irradiated is incident on the half mirror 6. The light flux reflected by the half mirror 6 is reflected by the mirror 7 toward the detection element 3. At this time, since the optical axis is lengthened by the distance between the half mirror 6 and the mirror 7, the focal point is formed at the front focal position (the front pin position) before the design focal position (the surface of the detection element 2). Therefore, the front focal image (front pin image) that passes through the front focal position is detected by the detection element 3. The Light flux that passes through the half mirror 6 is incident on the glass block 8. While the light flux passing through the glass block 8, the refractive index thereof changes, and the incident light flux travels in a state close to parallel light. Therefore, the light flux that passes through the glass block 8 forms a focal point at the rear focal position (rear pin position) behind the design focal position (the surface of the detection element 2). Therefore, the rear focal image (rear pin image) before reaching the rear focal position is detected by the detection element 3 different from the detection element 3 that captures the front focal image. As a result, the plurality of detection elements 3 for focus detection of the imaging sensor 105 (205) can capture the front focal image and the rear focal image. When viewed from the detection surface of the imaging sensor 105 (205) that is a design focal position, the front focal position and the rear focal position are preferably formed at the same distance.

Both the plurality of detection elements 2 and the plurality of detection elements 3 are irradiated with the light flux by the same detection optical system 176. Therefore, as the image for focus adjustment captured by the plurality of detection elements 3, an image having the same numerical aperture (NA) as the pattern image to be the inspection image of the substrate 101 can be used.

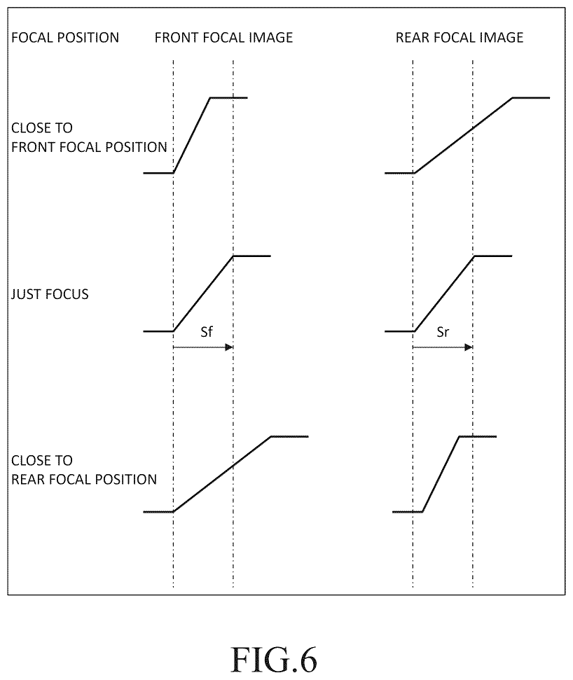

FIG. 6 is a diagram illustrating an example of the focus detection method according to First Embodiment. The example of FIG. 6 illustrates a case where an edge of a pattern is imaged. When the focal position of the light flux incident on the imaging sensor 105 (205) is the position (just focus) of the detection surface of the imaging sensor 105 (205), the blur amount of the front focal image and the blur amount of the rear focal image are the same amount. In other words, the rising angle (or falling angle) of the edge of the front focal image and the rising angle (or falling angle) of the edge of the back focal image are the same angle. Meanwhile, when the focal position of the light flux incident on the imaging sensor 105 (205) is a position close to the front focal, the blur amount of the front focal image is smaller than the blur amount of the rear focal image. In other words, the front focal image is an image in which the rising of the edge is steep, and conversely, the rear focal image is an image in which the rising of the edge is gentle. Conversely, when the focal position of the light flux incident on the imaging sensor 105 (205) is a position close to the rear focal, the blur amount of the rear focal image is smaller than the blur amount of the front focal image. In other words, the rear focal image is an image in which the rising of the edge is steep, and conversely, the front focal image is an image in which the rising of the edge is gentle. Therefore, the focal position can be matched with the detection surface of the imaging sensor by adjusting a rising distance Sf (or the falling distance) of the edge of the front focal image and a rising distance Sr (or the falling distance) of the edge of the rear focal image to be the same.

Next, a specific operation of the inspection apparatus 100 is described.

As the optical image acquisition process, the optical image acquisition mechanism 150 acquires an optical image of the substrate 101. The imaging sensor 105 receives the light flux (first light flux) transmitted through or reflected by a region (first region) of the substrate 101 (target object). In the examples of FIGS. 1 and 3, the imaging sensor 105 receives the light flux (first light flux) obtained by reflecting a reflection visual field region (first region) of the substrate 101 (target object). Specifically, the operation is as follows. In the pattern formed on the substrate 101, the beam splitter 174 is irradiated with a portion (for example, DUV light) of laser light having a wavelength in the ultraviolet range or less generated from the light source 103 as inspection light by the reflection illumination optical system 171. The emitted inspection light is reflected by the beam splitter 174 and is emitted to the substrate 101 by the objective lens 104. Here, the substrate 101 is irradiated with the above-described inspection light of the reflection visual field. The light flux corresponding to the inspection light reflected from the substrate 101 passes through the objective lens 104, the beam splitter 174, and the first image forming lens 175 and travels to the separation mirror 177. Then, the optical image passes through, for example, a gap of the separation mirror 177, is formed, as an optical image, on the imaging sensor 105 by the detection optical system 176, and enters, and captures an optical image for reflection inspection. In the detection optical system 176, the collimator lens 178 guides the incident light flux to an image forming lens 189. Then, the image forming lens 189 forms an image of the incident light flux on the imaging sensor 105.

In such a case, the plurality of detection elements 3 for focus detection among the plurality of detection elements 1 of the imaging sensor 105 receives a portion of the light flux formed by the detection optical system 176 through the optical mechanism 35 and captures an optical image for focus detection.

The image of the pattern formed on the imaging sensor 105 is photoelectrically converted by each detection element 1 of the imaging sensor 105 and further subjected to analog/digital (A/D) conversion by the sensor circuit 106. The stripe pattern memory 123 stores data of pixel values of the k-th (n=k) inspection stripe 20 to be measured imaged by the plurality of detection elements 2 in the inspection region and optical image data for focus adjustment imaged by the plurality of detection elements 3 in the focus adjustment region. The measurement data (pixel data) is, for example, 8-bit unsigned data and expresses the gray scale level (light amount) of the brightness of each pixel. The data of the pixel value of the inspection stripe 20 to be inspected and the optical image data for focus adjustment are output to the comparison circuit 108 (for example, the comparison circuit 108a) together with the position information measured by a position circuit 107.

At the same time, the beam splitter 174 is irradiated with another portion of the laser light generated from the light source 103 as the measurement light by the reflection illumination optical system 171. The emitted measurement light is reflected by the beam splitter 174 and is emitted to the substrate 101 by the objective lens 104. Here, on the substrate 101, the autofocus visual field region adjacent to the reflection visual field region is irradiated with the measurement light of the autofocus image described above. The light flux corresponding to the measurement light reflected from the substrate 101 passes through the objective lens 104, the beam splitter 174, and the first image forming lens 175 and travels to the separation mirror 177. Then, the light flux is reflected by the separation mirror and travels to the focus optical system 180. Then, the light amount data measured by the light amount sensors 185 and 187 is output to the autofocus control circuit 140.

When the transmission inspection is simultaneously performed, the following operation is further performed.

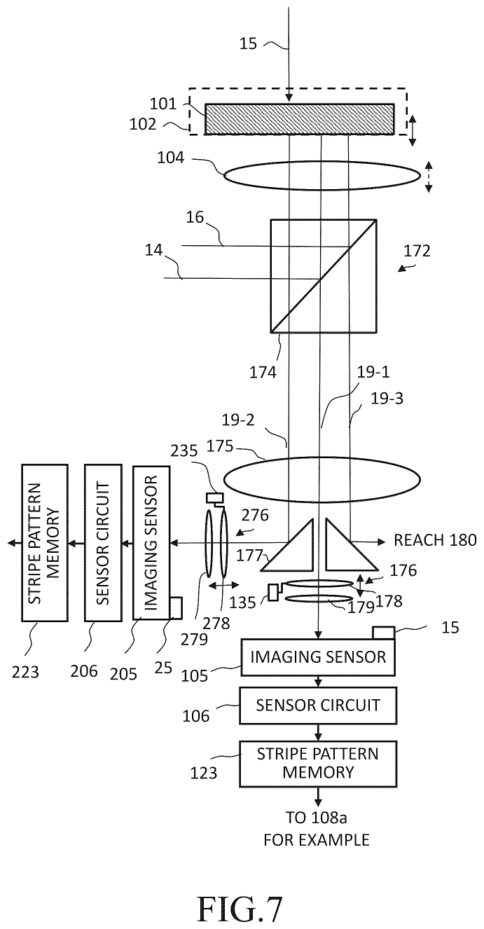

FIG. 7 is a diagram illustrating an example of a configuration in a case where the plurality of regions are simultaneously inspected according to First Embodiment. In the example of FIG. 7, an example of a case where the reflection inspection and the transmission inspection are simultaneously performed is illustrated. The present invention is not limited to such a combination, and the simultaneous inspection of the reflection inspection and the reflection inspection may be performed. Alternatively, the simultaneous inspection of the transmission inspection and the transmission inspection may be performed.

When the transmission inspection is simultaneously performed in addition to the reflection inspection, as illustrated in FIG. 7, a detection optical system 276, the imaging sensor 205, a sensor circuit 206, a stripe pattern memory 223, and an optical mechanism 25 are further arranged in the configuration of FIG. 1 for the transmission inspection. Also, in the separation mirror 177, for example, two mirrors are arranged so as to be back-to-back.

The imaging sensor 205 receives the light flux (second light flux) transmitted through or reflected by a region (second region) of the substrate 101 (target object) at the same timing as the imaging sensor 105. In the examples of FIGS. 7 and 3, the imaging sensor 205 receives light flux 19-2 (second light flux) transmitted through the transmission visual field region (second region) of the substrate 101 (target object). As described with reference to FIG. 4, the imaging sensor 205 includes the plurality of detection elements 2 (third detection elements) that capture a pattern image of, for example, a transmission visual field region (second region) of the substrate 101, and the plurality of detection elements 3 (fourth detection elements) that capture an image for focus detection. The plurality of detection elements 2 detects the light flux 19-2 (second light flux) transmitted through the transmission visual field region (second region) of the substrate 101 (target object) at the same timing as the imaging sensor 105 and captures a pattern image of the transmission visual field region (second region) of the substrate 101. The plurality of detection elements 3 are arranged adjacent to the plurality of detection elements 2, detect light fluxes obtained by shifting a focus position of the light flux 19-2 front side and rear side, and capture images for focus adjustment (focus detection). Specifically, the operation is as follows.

In the example of FIG. 7, when the substrate 101 is illuminated with inspection light 14 for reflection inspection, light flux 19-1 reflected by the substrate 101 is incident on the detection optical system 176 through, for example, a gap between two mirrors of the separation mirror 177.

When the substrate 101 is illuminated with measurement light 16 for autofocus, light flux 19-3 reflected by the substrate 101 is reflected by, for example, one of the two mirrors of separation mirror 177, and is incident on the focus optical system 180.

In addition, the substrate 101 is irradiated with another part of the laser light generated from the light source 103 by the transmitted illumination optical system 170 as inspection light 15 for transmission inspection. Here, on the substrate 101, the transmission visual field region adjacent to the reflection visual field region is irradiated with the inspection light 15 of the transmission visual field described above. The light flux 19-2 corresponding to the inspection light 15 transmitted through the substrate 101 passes through the objective lens 104, the beam splitter 174, and the first image forming lens 175 and travels to the separation mirror 177. Then, the light is reflected by the separation mirror, is formed as an optical image on the imaging sensor 205 by the detection optical system 276, is incident, and captures an optical image for transmission inspection.

In such a case, the plurality of detection elements 3 for focus detection among the plurality of detection elements 1 of the imaging sensor 205 receives a portion of the light flux formed by the detection optical system 276 through the optical mechanism 25 and captures an optical image for focus detection.

The image of the pattern formed on the imaging sensor 205 is photoelectrically converted by each detection element 1 of the imaging sensor 105 and further subjected to analog/digital (A/D) conversion by the sensor circuit 106. The stripe pattern memory 123 stores data of pixel values of the k-th (n=k) inspection stripe 20 to be measured imaged by the plurality of detection elements 2 in the inspection region and optical image data for focus adjustment imaged by the plurality of detection elements 3 in the focus adjustment region. The measurement data (pixel data) is, for example, 8-bit unsigned data and expresses the gray scale level (light amount) of the brightness of each pixel. The data of the pixel value of the inspection stripe 20 to be inspected and the optical image data for focus adjustment are output to the comparison circuit 108 (for example, the comparison circuit 108b) together with the position information measured by a position circuit 107.

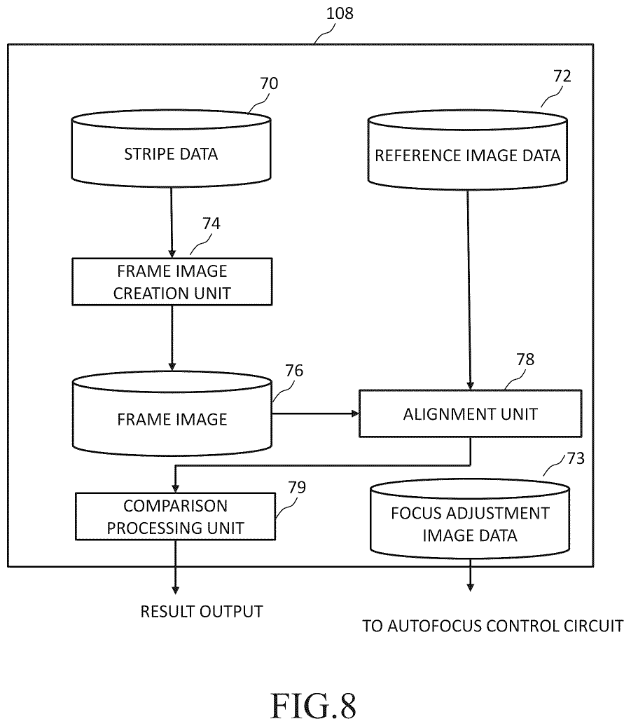

FIG. 8 is a diagram illustrating an example of an internal configuration of the comparison circuit according to First Embodiment. In FIG. 8, storage devices 70, 72, 73, and 76 such as magnetic disk drives, a frame image creation unit 74, an alignment unit 78, and a comparison processing unit 79 are arranged in the comparison circuit 108. A series of “units” such as the frame image creation unit 74, the alignment unit 78, and the comparison processing unit 79 includes a processing circuit. Such a processing circuit includes an electric circuit, a computer, a processor, a circuit board, a quantum circuit, a semiconductor device, or the like. In addition, each “unit” may use a common processing circuit (the same processing circuit). Alternatively, different processing circuits (separate processing circuits) may be used. Input data necessary for the frame image creation unit 74, the alignment unit 78, and the comparison processing unit 79 or a calculation result is stored in a memory (not illustrated) or the memory 111 in the comparison circuit 108 each time. When the plurality of comparison circuits 108a and 108b are arranged, for example, all the comparison circuits may have the same configuration.

The stripe data (stripe region image) of the inspection stripe 20 to be inspected input to the comparison circuit 108 is stored in the storage device 70. The optical image data for focus adjustment is stored in the storage device 73. The optical image data for focus adjustment is output to the autofocus control circuit 140.

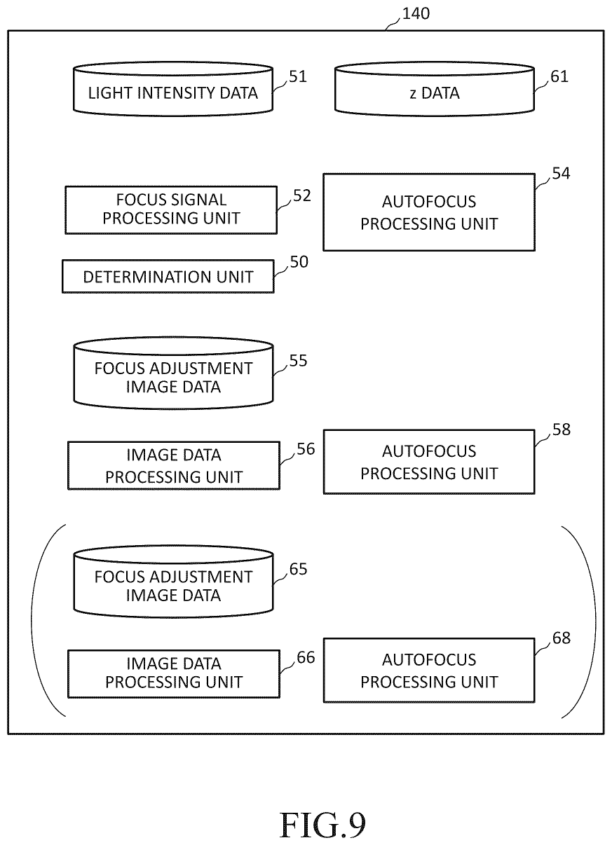

FIG. 9 is a diagram illustrating an example of the internal configuration of the autofocus control circuit according to First Embodiment. In FIG. 9, storage devices 51, 55, and 61 such as a magnetic disk drive, a determination unit 50, a focus signal processing unit 52 (focus signal calculation unit), an autofocus processing unit 54, an image data processing unit 56, and an autofocus processing unit 58 are arranged in the autofocus control circuit 140.

A series of “units” such as the determination unit 50, the focus signal processing unit 52, the autofocus processing unit 54, the image data processing unit 56, and the autofocus processing unit 58 includes a processing circuit. Such a processing circuit includes an electric circuit, a computer, a processor, a circuit board, a quantum circuit, a semiconductor device, or the like. In addition, each “unit” may use a common processing circuit (the same processing circuit). Alternatively, different processing circuits (separate processing circuits) may be used. Input data or calculation results necessary for the determination unit 50, the focus signal processing unit 52, the autofocus processing unit 54, the image data processing unit 56, and the autofocus processing unit 58 are stored in a memory (not illustrated) or the memory 111 in the autofocus control circuit 140 each time.

When the transmission inspection is simultaneously performed, a storage device 65, an image data processing unit 66, and an autofocus processing unit 68 are further arranged.

Front focal image data and rear focal image data for focus adjustment captured by the imaging sensor 105 are stored in the storage device 55.

First, the determination unit 50 determines whether the images captured by the plurality of detection elements 3 in the focus adjustment region are effective for focus detection. Specifically, the determination unit 50 reads the front focal image data and the rear focal image data for focus adjustment from the storage device 55 and determines whether both the images are effective for focus detection. As described with reference to FIG. 6, the focal position can be matched with the detection surface of the imaging sensor by adjusting the rising distance Sf (or the falling distance) of the edge of the front focal image for focus detection and the rising distance Sr (or the falling distance) of the edge of the rear focal image to be the same. Therefore, when a region without a pattern is imaged, or when a solid region that does not cross a pattern edge is imaged, determination becomes difficult. In case of the image of the region for which determination is difficult, it is determined that the image is not effective for focus detection. When the region across the pattern edge is imaged, it is determined that the image is effective for focus detection.

The autofocus control circuit 140 controls the drive mechanism 135 and the autofocus mechanism 131 so that, when the images captured by the plurality of detection elements 3 are effective for focus detection, focus adjustment of the light flux 19-1 is performed by the drive mechanism 135 (adjustment mechanism) controlled by the autofocus processing unit 58, and when the images captured by the plurality of detection elements 3 are not effective for focus detection, focus adjustment of the reflected light (the light flux 19-3) for autofocus is performed by the autofocus mechanism 131 controlled by the autofocus processing unit 54. Specifically, it operates as follows.

When it is determined that image data is effective for focus detection in a step of processing image data for focus adjustment, the image data processing unit 56 first extracts edge profiles indicating paired edge positions from the front focal image data and the rear focal image data captured by the imaging sensor 105.

Next, the image data processing unit 56 calculates the rising distance Sf (or the falling distance) of the edge of the front focal image and the rising distance Sr (or the falling distance) of the edge of the rear focal image.

The image data processing unit 56 calculates, for example, the movement amount of the collimator lens 178 for matching the focal position with the detection surface of the imaging sensor 105 from the difference between the rising distance Sf (or the falling distance) of the edge of the front focal image and the rising distance Sr (or the falling distance) of the edge of the rear focal image. The relationship between the difference between the rising distance Sf (or the falling distance) of the edge of the front focal image and the rising distance Sr (or the falling distance) of the edge of the rear focal image and the movement amount of the collimator lens 178 may be calculated in advance by experiment, simulation, or the like.

In a focus adjustment step, the autofocus processing unit 58 controls the drive mechanism 135. Then, the drive mechanism 135 (adjustment mechanism) adjusts the focal position of the light flux 19-1 using the images for focus adjustment captured by the plurality of detection elements 3 of the imaging sensor 105. In other words, the focal position of the light flux 19-1 is adjusted using the images projected on the plurality of detection elements 3 at the end portion of the imaging sensor 105. Specifically, the drive mechanism 135 (adjustment mechanism) adjusts the focal position of the light flux 19-1 incident on the imaging sensor 105 by moving the collimator lens 178 by the calculated movement amount.

Note that, in the example of FIG. 1, the case where the collimator lens 178 is moved is described, but the present invention is not limited thereto. The drive mechanism 135 (adjustment mechanism) adjusts the focal position of the light flux 19-1 by moving at least one of the image forming lens 189 and the collimator lens 178 in the optical axis direction in real time. For example, the focal position of the light flux 19-1 incident on the imaging sensor 105 may be adjusted by moving the image forming lens 179. Alternatively, the focal position of the light flux 19-1 incident on the imaging sensor 105 may be adjusted by moving both the collimator lens 178 and the image forming lens 189.

When the transmission inspection is simultaneously performed, the focal positions of the light flux 19-2 incident on the imaging sensor 205 are individually adjusted in parallel independently of the reflection inspection. Specifically, the operation is as follows.

First, front focal image data and rear focal image data for focus adjustment captured by the imaging sensor 205 are stored in the storage device 65.

When it is determined that image data is effective for focus detection in a step of processing image data for focus adjustment, the image data processing unit 66 first extracts edge profiles indicating paired edge positions from the front focal image data and the rear focal image data captured by the imaging sensor 205.

Next, the image data processing unit 66 calculates the rising distance Sf (or the falling distance) of the edge of the front focal image and the rising distance Sr (or the falling distance) of the edge of the rear focal image.

The image data processing unit 66 calculates, for example, the movement amount of a collimator lens 278 for matching the focal position with the detection surface of the imaging sensor 205 from the difference between the rising distance Sf (or the falling distance) of the edge of the front focal image and the rising distance Sr (or the falling distance) of the edge of the rear focal image. The relationship between the difference between the rising distance Sf (or the falling distance) of the edge of the front focal image and the rising distance Sr (or the falling distance) of the edge of the rear focal image and the movement amount of the collimator lens 278 may be calculated in advance by experiment, simulation, or the like.

In a focus adjustment step, the autofocus processing unit 68 controls a drive mechanism 235. Then, the drive mechanism 235 (adjustment mechanism) adjusts the focal position of the light flux 19-2 using the images for focus adjustment captured by the plurality of detection elements 3 of the imaging sensor 205. In other words, the focal position of the light flux 19-2 is adjusted using the images projected on the plurality of detection elements 3 at the end portion of the imaging sensor 205. The adjustment method is similar to the case of the imaging sensor 105.

Note that, the case where the collimator lens 278 is moved is described, but the present invention is not limited thereto similarly to the focus adjustment on the imaging sensor 105. For example, the focal position of the light flux 19-2 incident on the imaging sensor 205 may be adjusted by moving an image forming lens 279. Alternatively, the focal position of the light flux 19-2 incident on the imaging sensor 205 may be adjusted by moving both the collimator lens 278 and an image forming lens 289.

When it is determined that the images captured by the plurality of detection elements 3 are not effective for focus detection, focus adjustment is performed by the autofocus mechanism 131. The autofocus mechanism 131 detects reflected light for autofocus reflected by the substrate 101 illuminated with the measurement light 16 for autofocus and adjusts the height position of the pattern formed surface of the substrate 101 to adjust the focus of the autofocus reflected light. Specifically, it operates as follows.

The light flux incident on the focus optical system 180 is refracted in the condensing direction by the image forming optical system 181 and is emitted to the beam splitter 182. A part of the light transmitted by the beam splitter 182 is limited by the slit plate 184 at the front focal position (front pin position), and the light amount of the light passing through the slit plate 184 is measured by the light amount sensor 185. A part of the light split by the beam splitter 182 is limited by the slit plate 186 at the rear focal position (rear pin position), and the light amount of the light passing through the slit plate 186 is measured by the light amount sensor 187. Thus, the light amount at the front focal position and the light amount at the rear focal position can be measured. Light amount data (light intensity data) of the light amount at the front focal position and the light amount at the rear focal position measured during scanning is output to the autofocus control circuit 140 and stored in the storage device 51. Information (z data) on the height position of the pattern formed surface of the substrate 101 measured by the position sensor 134 is stored in the storage device 61.

As the focus signal calculation step, the focus signal processing unit 52 calculates the focus signal using the measured light amount at the front focal position and the measured light amount at the rear focal position. The focus signal (f) is defined by Formula (1) using a light amount A at the front focal position and a light amount B at the rear focal position.

f=(A−B)/(A+B) (1)

As the autofocus step, under the control of the autofocus processing unit 54, the Z drive mechanism 132 variably drives the height position of the XYθ table 102 so that the focus signal (f) becomes 0, for example, to perform the autofocus operation.

As described above, each inspection stripe 20 is scanned while the focus of the light flux 19-1 on the imaging sensor 105 is directly adjusted in real time by driving the detection optical system 176. Furthermore, when focus adjustment cannot be performed by driving the detection optical system 176, the autofocus mechanism 131 variably drives the height position of the XYθ table 102 to indirectly adjust the focus of the light flux 19-1 on the imaging sensor 105 in real time. Note that, in design, the imaging sensor 105 is disposed so as to be conjugate with the focal position of the objective lens 104 on the substrate 101 side. As a result, when the height position of the pattern formed surface of the substrate 101 is in focus, the focal position of the light flux 19-1 is also focused on the inspection surface of the imaging sensor 105 in design. However, since the height position may be out of focus in practice, the focal position can be principally focused with high accuracy by directly adjusting by driving the detection optical system 176.

As the reference image creation step, the reference image creation circuit 112 creates a reference image to be a reference using the figure pattern data (design data). The reference image is created for each inspection stripe 20 in parallel with the scanning operation of the inspection stripe 20. Specifically, it operates as follows. The reference image creation circuit 112 inputs figure pattern data (design data) for each frame region 30 of the target inspection stripe 20 and converts each figure pattern defined in the figure pattern data into binary or multi-valued image data.

The figure defined in the figure pattern data is, for example, a rectangle or a triangle as a basic figure, and for example, figure data in which the shape, size, position, and the like of each pattern figure are defined by information such as coordinates (x, y) at a reference position of the figure, a length of a side, and a figure code serving as an identifier to distinguish a figure type such as a rectangle or a triangle is stored.

When design pattern data to be such figure data is input to the reference image creation circuit 112, the design pattern data is expanded to data for each figure, and a figure code indicating a figure shape of the figure data, figure dimensions, and the like are interpreted. Then, the design pattern data is developed into binary or multi-valued design pattern image data as a pattern arranged in a square having a grid of a predetermined quantization dimension as a unit, and output. In other words, the design data is read, the occupancy of the figure in the design pattern is calculated for each square formed by virtually dividing the frame region as a square having a predetermined dimension as a unit, and n-bit occupancy data (design image data) is output. For example, it is preferable to set one square as one pixel. Then, if it is assumed that one pixel has a resolution of 1/2⁸ (=1/256), a small region of 1/256 is allocated by the region of the figure arranged in the pixel, and the occupancy in the pixel is calculated. Then, the design data is created as data of 8-bit occupancy. The square (inspection pixel) may be matched with the pixel of the measurement data.

Next, the reference image creation circuit 112 performs filter processing on design image data of a design pattern that is image data of a figure using a filter function.

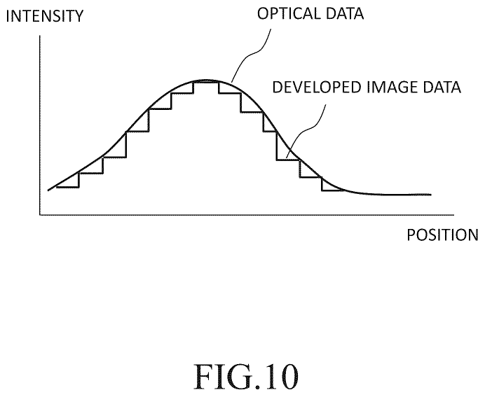

FIG. 10 is a diagram illustrating the filter processing according to First Embodiment. The pixel data of the optical image captured from the substrate 101 is in a state in which a filter acts due to resolution characteristics of an optical system used for imaging, or the like, in other words, in an analog state that continuously changes, and thus, for example, as illustrated in FIG. 10, the image intensity (gray value) is different from the developed image (design image) having a digital value. Meanwhile, since the figure pattern data is defined by the figure code or the like as described above, the image intensity (gray value) may be a digital value in the developed design image. Therefore, the reference image creation circuit 112 performs an image treatment (filter processing) on the developed image to create a reference image close to the optical image. As a result, design image data that is image data on the design side in which the image intensity (gray value) is a digital value can be matched with the image generation characteristics of the measurement data (optical image). The created reference image is output to the comparison circuit 108. The reference image data input to the comparison circuit 108 is stored in the storage device 72.

As a comparison step, the comparison circuit 108 (comparison unit) compares pattern images captured by the plurality of detection elements 2 of the imaging sensor 105 with corresponding reference images. Specifically, it operates as follows.

In the comparison circuit 108, first, the frame image creation unit 74 generates a plurality of frame images 31 obtained by dividing a stripe region image (optical image) by a predetermined width. Specifically, as illustrated in FIG. 2, the stripe region image is divided into frame images of the plurality of rectangular frame regions 30. For example, the image is divided into a size of 512×512 pixels. The data of each frame region 30 is stored in the storage device 76.

Next, the alignment unit 78 reads the corresponding frame image 31 and the corresponding reference image from the storage devices 72 and 76 for each frame region 30 and aligns the frame image 31 and the corresponding reference image by a predetermined algorithm. For example, the alignment is performed using a least squares method.

Then, the comparison processing unit 79 (another example of the comparison unit) compares the frame image 31 with the reference image corresponding to the frame image 31. For example, comparison is performed for each pixel. Here, both are compared for each pixel according to a predetermined determination condition, and for example, the presence or absence of a defect such as a shape defect is determined. As a determination condition, for example, both are compared for each pixel according to a predetermined algorithm to determine the presence or absence of a defect. For example, a difference value between pixel values of both images is calculated for each pixel, and a case where the difference value is larger than the threshold value Th is determined as a defect. Then, the comparison result may be output to, for example, the magnetic disk device 109, the magnetic tape device 115, the flexible disk device (FD) 116, the CRT 117, and the pattern monitor 118 or may be output from the printer 119.

In the above-described example, the case of the die-database inspection is described, but the die-die inspection may be used. In such a case, the comparison circuit 108 uses the frame image (optical image) of the die 2 acquired for one region of the frame regions as a reference (reference image) for the frame regions to be subjected to the die-die inspection among the plurality of frame regions 30. First, the alignment unit 78 reads the frame image 31 of the corresponding die 1 and the frame image of the die 2 from the storage device 76 for each frame region 30 in which the die-die inspection is performed, and aligns the frame image 31 of the die 1 and the frame image of the die 2 by a predetermined algorithm. For example, the alignment is performed using a least squares method. Then, the comparison processing unit 79 (comparison unit) compares the frame image 31 of the corresponding die 1 with the frame image of the die 2 for each pixel for each frame region 30 in which the die-die inspection is performed.

When the transmission inspection is simultaneously performed, the stripe data for transmission inspection is output to, for example, the comparison circuit 108b different from the comparison circuit 108a for reflection inspection. The reference image is also output to the comparison circuit 108b separately from the reflection inspection. Then, a comparison process is performed similarly to the content described above, and a comparison result is output.

As described above, according to First Embodiment, the focal position of the light flux 19-1 (19-2) can be directly adjusted to the detection surface of the imaging sensor 105 (205) by the detection optical system 176 (276) using the focus adjustment image under the same imaging condition as the inspection image. In addition, even when simultaneous inspection of reflection inspection/transmission inspection, simultaneous inspection of reflection inspection/reflection inspection, or simultaneous inspection of transmission inspection/transmission inspection is performed, focus adjustment can be individually performed independently for each imaging sensor. Therefore, the focus can be adjusted without depending on the illumination condition or the pattern formed on the inspected substrate 101.

### Second Embodiment

In First Embodiment, the configuration in which the focal position of the light flux immediately before incidence on the imaging sensor 105 (205) is shifted front side and rear side using the optical mechanism 35 (25) is described, but the method of creating the image for focus adjustment is not limited thereto. In Second Embodiment, a configuration for treating the inspection light 14 before irradiating the substrate 101 is described. Hereinafter, contents other than the points particularly described are the same as those in First Embodiment.

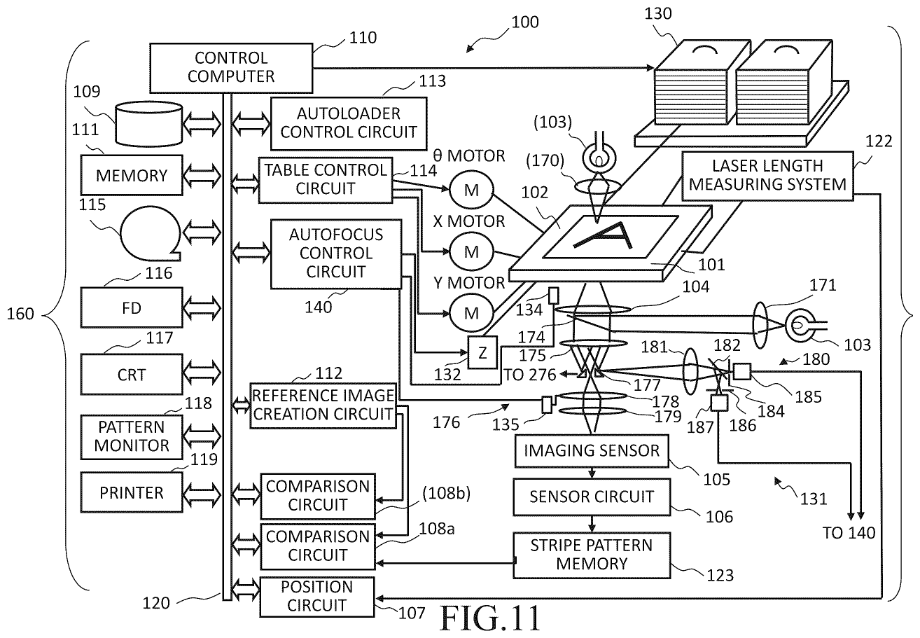

FIG. 11 is a configuration diagram illustrating a configuration of a pattern inspection apparatus according to Second Embodiment. FIG. 11 is the same as FIG. 1 except that the optical mechanism 35 is removed.

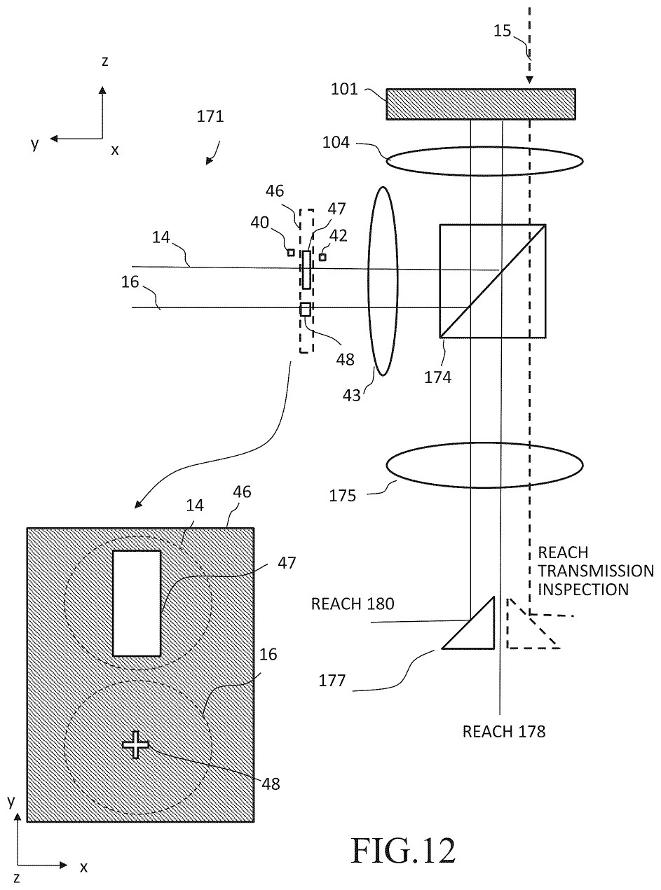

FIG. 12 is a diagram illustrating an example of a field stop image of inspection light and measurement light according to Second Embodiment. As illustrated in FIG. 12, the inspection light 14 for reflection inspection illuminates the entire field stop opening 47 formed in a field stop plate 46, so that the passing light flux is limited, and a field stop image of the reflection visual field of the inspection light 14 is formed. Similarly, the measurement light 16 for autofocus illuminates the entire field stop opening 48 formed in the field stop plate 46, so that the passing light flux is limited, and an autofocus image of the autofocus visual field of the measurement light 16 is formed. Then, the substrate 101 is irradiated with the field stop image of the reflection visual field of the inspection light 14 and the autofocus image of the autofocus visual field of the measurement light 16 by a magnifying optical system 194. When the transmission inspection is performed, the same applies to the inspection light 15 for the transmission inspection.

Here, in Second Embodiment, a front focal illumination pattern 40 and a rear focal illumination pattern 42 are arranged on the front side and rear side (forward and backward) of the field stop opening 47 in the optical axis direction so as not to overlap a partial region of the field stop opening 47.

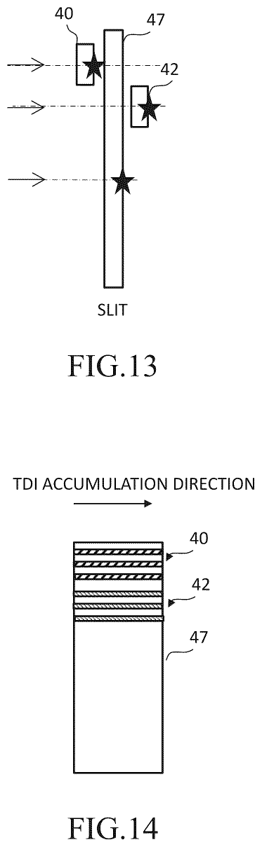

FIG. 13 is a diagram illustrating arrangement positions of a front focal illumination pattern and a rear focal illumination pattern according to Second Embodiment.

FIG. 14 is a diagram illustrating an example of a front view of the front focal illumination pattern and the rear focal illumination pattern according to Second Embodiment.

The front focal illumination pattern 40 is arranged at a front focal position before a focal position of a field stop image formed by the field stop opening 47 in the optical axis direction. The rear focal illumination pattern 42 is arranged at a rear focal position behind the focal position of the field stop image formed by the field stop opening 47 in the optical axis direction. The front focal illumination pattern 40 and the rear focal illumination pattern 42 are both formed in, for example, a Line-and-space pattern. When an image is captured by the imaging sensor 105, it is preferable that the line-and-space patterns are repeatedly arranged in a direction orthogonal to the TDI accumulation direction. The front focal illumination pattern 40 and the rear focal illumination pattern 42 are arranged at positions overlapping the region of the end portion of the field stop opening 47.

In the field stop image of the inspection light 15, light flux portions transmitted through or reflected by the substrate 101 on which the inspection light portions having passed through the front focal illumination pattern 40 and the rear focal illumination pattern 42 are illuminated are detected by the plurality of detection elements 3 of the imaging sensor 105. The detection element 3 that receives, for example, reflected light of the front focal illumination pattern captures an image formed at the front focal position. The detection element 3 that receives, for example, reflected light of the rear focal illumination pattern captures an image formed at the rear focal position. A light flux portion transmitted through or reflected by the substrate 101 illuminated with the inspection light portion of the remainder of the field stop image of the inspection light 14 is detected by the plurality of detection elements 2 of the imaging sensor 105 and becomes an optical image to be inspected.

As described above, by arranging the front focal illumination pattern 40 on the front side of the illumination field stop in an optical axis direction and the rear focal illumination pattern 42 on the rear side of the illumination field stop in the optical axis direction, the front focal image and the rear focal image can be captured without arranging the optical mechanism 35 in front of the imaging sensor 105.

Further, by illuminating the substrate 101 with the image of the front focal illumination pattern 40 and the image of the rear focal illumination pattern 42, the image for focus adjustment can be captured by the imaging sensor 105 even when there is no pattern at the illuminated position of the substrate 101. The focus adjustment method using the obtained image is similar to that of First Embodiment.

Therefore, the determination by the determination unit 50 performed in First Embodiment can be omitted, and the focal position of the light flux 19-1 (19-2) can be directly adjusted to the detection surface of the imaging sensor 105 (205) by the detection optical system 176 (276) using the image for focus adjustment under the same imaging condition as the inspection image.

When the transmission inspection is simultaneously performed, focus adjustment can be performed on the inspection light 15 for the transmission inspection by a similar method by arranging the front focal illumination pattern 40 and the rear focal illumination pattern 42 on the front side and rear side of the field stop opening in an optical axis direction.

Since the period and the phase of the illumination pattern are known, the illumination pattern can be distinguished from the substrate pattern. In addition, when a substrate pattern similar to the illumination pattern continues over a long region, the focus error can be reduced by devising to provide a plurality of different periods in the illumination pattern.

As described above, according to Second Embodiment, the same effects as those of First Embodiment can be obtained. Further, even when there is no pattern at the illuminated position of the substrate 101, an image for focus adjustment can be captured by the imaging sensor 105, and thus the autofocus mechanism 131 can be omitted.

The embodiments are described above with reference to specific examples. However, the present invention is not limited to these specific examples.

In addition, although descriptions of portions and the like that are not directly necessary for the description of the present invention, such as a device configuration and a control method, are omitted, a required device configuration and control method can be appropriately selected and used. For example, the description of the controller configuration for controlling the inspection apparatus 100 is omitted, but it is obvious that a necessary controller configuration is appropriately selected and used.

In addition, all pattern inspection apparatuses that include the elements of the present invention and can be appropriately changed in design by those skilled in the art are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern inspection apparatus comprising:
a movable stage on which a target object on which a pattern is formed is placed;
an imaging sensor including a plurality of first detection elements that detect light flux transmitted through or reflected by the target object illuminated with inspection light and capture a pattern image of the target object, and a plurality of second detection elements that are arranged adjacent to the plurality of first detection elements, detect light fluxes obtained by shifting a focus position of the light flux front side and rear side, and capture images for focus adjustment;
an adjustment mechanism configured to adjust a focal position of the light flux by using the images for the focus adjustment captured by the plurality of second detection elements; and
a comparison circuit configured to compare the pattern image captured by the plurality of first detection elements and a predetermined reference image.

2. The apparatus according to claim 1, wherein an image having a same numerical aperture as the pattern image of the target object is used as the images for focus adjustment captured by the plurality of second detection elements.

3. The apparatus according to claim 1, wherein the imaging sensor uses a time delay integration (TDI) method and includes the plurality of second detection elements at end portions in a direction orthogonal to a TDI accumulation direction, and
the focal position of the light flux is adjusted using images projected on the plurality of second detection elements at the end portions.

4. The apparatus according to claim 1, further comprising:
an image forming lens configured to form an image of the light flux on the imaging sensor; and
a collimator lens configured to guide the light flux to the image forming lens,
wherein the adjustment mechanism adjusts the focal position of the light flux by moving at least one of the image forming lens and the collimator lens in an optical axis direction in real time.

5. The apparatus according to claim 1,
wherein the imaging sensor receives, as a first imaging sensor, a first light flux transmitted through or reflected by a first region of the target object,
the apparatus further comprising:
a second imaging sensor including a plurality of third detection elements that detect second light flux transmitted through or reflected by a second region of the target object at a same timing as the first imaging sensor and capture a pattern image of the second region of the target object, and a plurality of fourth detection elements that are arranged adjacent to the plurality of third detection elements, detect light fluxes obtained by shifting a focus position of the second light flux front side and rear side, and capture an image for focus adjustment.

6. The apparatus according to claim 1, further comprising:
a field stop plate in which a field stop opening is formed and forms a field stop image of the inspection light by the inspection light illuminating the entire field stop opening; and
a front pattern and a rear pattern that are arranged on a front side and a rear side of the field stop opening in an optical axis direction so as not to be overlapped with a portion of a region of the field stop opening,
wherein light flux portions transmitted through or reflected by the target object illuminated with inspection light portions passing through the front pattern and the rear pattern among the field stop image of the inspection light are detected by the plurality of second detection elements, and
the light flux portion transmitted through or reflected by the target object illuminated with an inspection light portion of a remainder of the field stop image of the inspection light is detected by the plurality of first detection elements.

7. The apparatus according to claim 1, further comprising an optical mechanism that is disposed in front of the plurality of second detection elements in an optical axis direction and moves the focal position of the light flux forward and backward.

8. The apparatus according to claim 7, further comprising:
an autofocus mechanism configured to detect reflected light for autofocus reflected by the target object illuminated with measurement light for autofocus and perform focus adjustment of the reflected Light for autofocus by adjusting a height position of a pattern formed surface of the target object;
a determination circuit configured to determine whether the image captured by the plurality of second detection elements is effective for focus detection; and
a control circuit configured to control the adjustment mechanism and the autofocus mechanism so that focus adjustment of the light flux is performed by the adjustment mechanism in a case that the image captured by the plurality of second detection elements is effective for focus detection, and focus adjustment of the reflected light for autofocus is performed by the autofocus mechanism in a case that the image captured by the plurality of second detection elements is not effective for focus detection.

9. The apparatus according to claim 1, wherein a number of the plurality of second detection elements is smaller than a number of the plurality of first detection elements.

10. The apparatus according to claim 7,
wherein the optical mechanism includes:
a half mirror;
a mirror; and
a glass block.
